(19) United States
(12) Patent Application Publication
(10) Pub. No.: US 2007/0261732 A1
(43) Pub. Date: Nov. 15, 2007

(54) Cable structure with a solar-powered layer

(76) Inventor: Sheng-Hsin Liao, Shulin City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/640,265

(22) Filed: Dec. 18, 2006

(30) Foreign Application Priority Data
May 12, 2006 (TW) 95117030

(51) Int. Cl. H01L 31/00

(52) U.S. Cl. 136/256

(57) ABSTRACT

A cable structure with a solar-powered layer includes a cable and at least one solar-powered photoelectric layer. The solar-powered photoelectric layer is disposed on a periphery of the cable. The solar-powered photoelectric layer is electrically connected to a conductor, so that the cable structure can absorb solar energy and convert it into electricity. The present invention reduces the amount of power that needs to be drawn from a power grid.

### BACKGROUND OF THE INVENTION

1. Field of the Invention

The present invention relates to a cable structure with a solar-powered layer, and in particular, to a cable structure that can be adapted to a LAN (local area network) cable, a USB cable, a power cable, or a signal cable etc. and utilizes solar energy to generate electric power to reduce the amount of power that needs to be drawn from a power grid.

2. Description of the Related Art

A conventional cable is mainly used to transmit electricity or signals, and is composed of a plurality of leading wires, insulating layers covered around the leading wires, and a covering layer. Such cables, i.e. a LAN cable, a USB cable, or a power cable, are becoming used to connect electric products more and more widely both indoors and out due to the progression of computer technology. However, these cables that are used to connect electric products only transmit electricity or signal and do not generate electricity themselves.

Therefore, the present invention, according to the disadvantages of the prior art, provides a new cable structure to overcome the above-mentioned drawbacks.

### SUMMARY OF THE INVENTION

It is a primary object of the present invention to provide a cable structure with a solar-powered layer, which has the function of generating electricity from solar energy. The cable can generate electricity for electronic products to reduces the amount of power that needs to be drawn from a power grid and reduce dependence on nonrenewable energy resources, and improve the inconveniences of often recharging or changing battery for electronic products.

In order to achieve the main object, the present invention provides a cable structure with a solar-powered layer, which includes a cable and at least one solar-powered photoelectric layer that is disposed on the periphery of the cable.

### BRIEF DESCRIPTION OF THE DRAWINGS

The invention will be better understood and objects other than those set forth above will become apparent when consideration is given to the following detailed description thereof. The description makes reference to the annexed drawings wherein:

FIG. 1 is a perspective view of a cable structure with a solar-powered layer of a first embodiment according to the present invention;

FIG. 1A is an enlarged perspective view of part A in FIG. 1;

FIG. 2 is another perspective view of a cable structure with a solar-powered layer of the first embodiment according to the present invention;

FIG. 3 is a perspective view of a cable structure with a solar-powered layer of a second embodiment according to the present invention;

FIG. 4A is a perspective view of a cable structure with a solar-powered layer of a third embodiment according to the present invention;

FIG. 4B is a perspective view of a cable structure with a solar-powered layer of a fourth embodiment according to the present invention;

FIG. 5 is a perspective view of a cable structure with a solar-powered layer of a fifth embodiment according to the present invention;

FIG. 6 is a perspective view of a cable structure with a solar-powered layer of a sixth embodiment according to the present invention;

FIG. 7 is a perspective view of a cable structure with a solar-powered layer of a seventh embodiment according to the present invention; and

FIG. 8 is a perspective view of a cable structure with a solar-powered layer of an eighth embodiment according to the present invention.

### DETAILED DESCRIPTION OF THE PREFERRED EMBODIMENTS

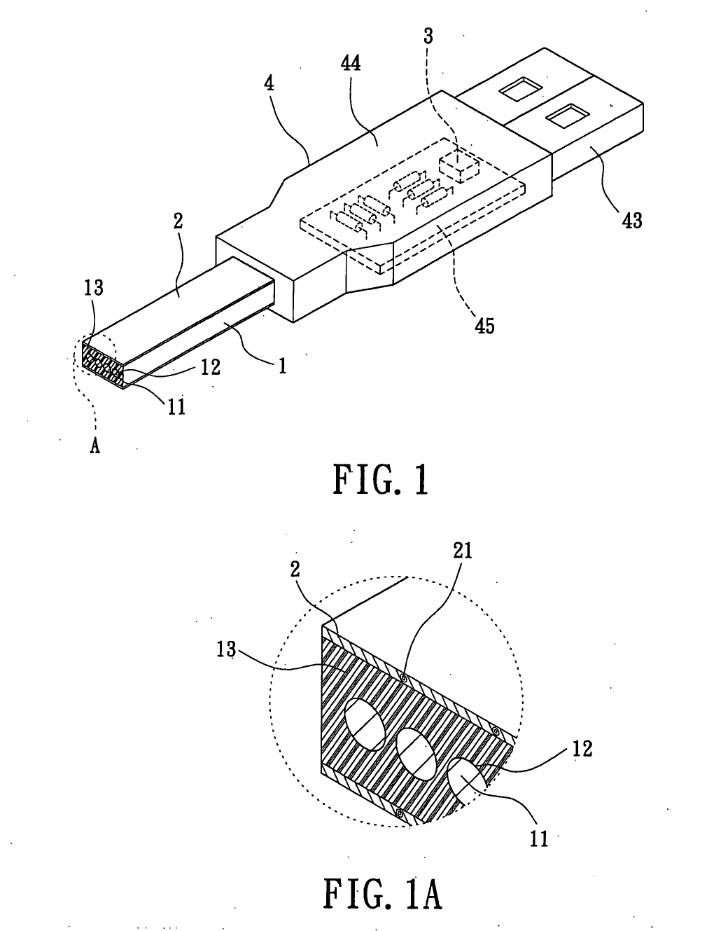

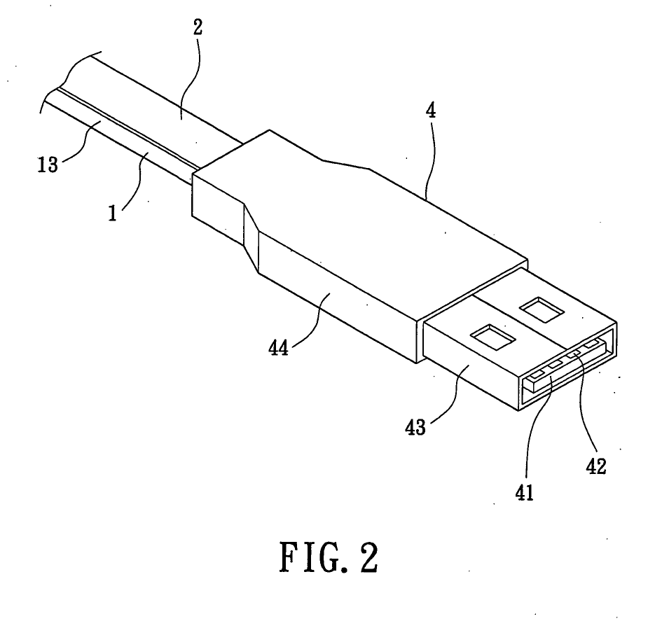

Reference is made to FIGS. 1, 1a and 2. The present invention provides a cable structure with a solar-powered layer, which includes a cable 1, at least one solar-powered photoelectric layer 2, and an accumulator 3. In this embodiment, the cable 1 has one end that connects with an electric connector 4. The electric connector 4 can be a USB connector. The electric connector 4 includes an insulative body 41, a plurality of terminals 42 disposed on the insulative body 41, a metal casing 43 covering the insulative body 41 and the terminals 42, and an insulative housing 44 covering a rear portion of the metal casing 43. The insulative housing 44 has a printed circuit board 45 disposed therein, and the terminals 42 have rear ends electrically connected to the printed circuit board 45. The cable 1 has one end electrically connected with the printed circuit board 45, and enables the cable 1 to electrically connect with the terminals 42 via the printed circuit board 45.

In this embodiment, the cable 1 includes a plurality of leading wires 11, and a plurality of insulative layers 12 covering the leading wire 11 and the covering layer 13. The cable 1 can be utilized to transmit power and signals. However, the cable 1 is not limited by the above-mentioned type or structure, and it can be various types and structure of power cable or signal cable.

The solar-powered photoelectric layer 2 can absorb solar energy and convert it into electric power. The solar-powered photoelectric layer 2 is disposed on a periphery of the cable 1. In other words, the solar-powered photoelectric layer 2 is disposed on a periphery of the covering layer 13 of the cable 1 which forms the solar-powered layer. In this embodiment, the cable 1 is a flat cable, and the two solar-powered photoelectric layers 2 are disposed on a top surface and a bottom surface of the covering layer 13 of the cable 1, respectively. The solar-powered photoelectric layer 2 can also be only disposed on a top surface and a bottom surface of the covering layer 13 of the cable 1, or on other positions.

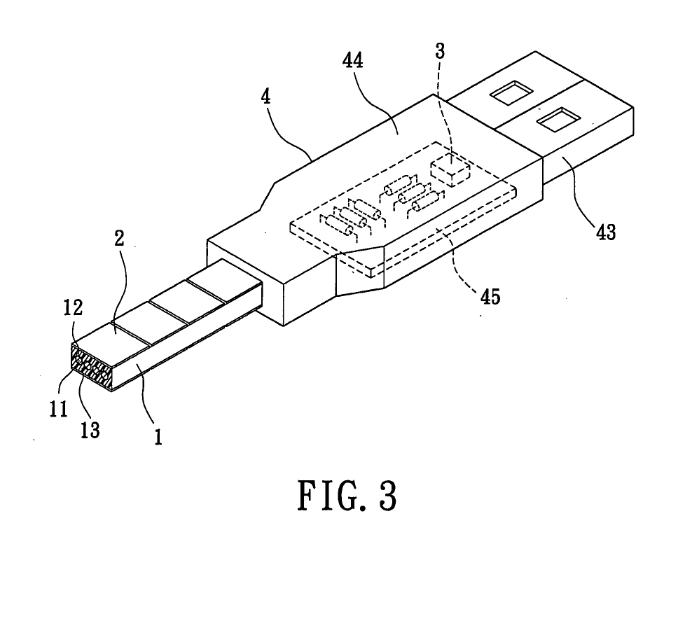

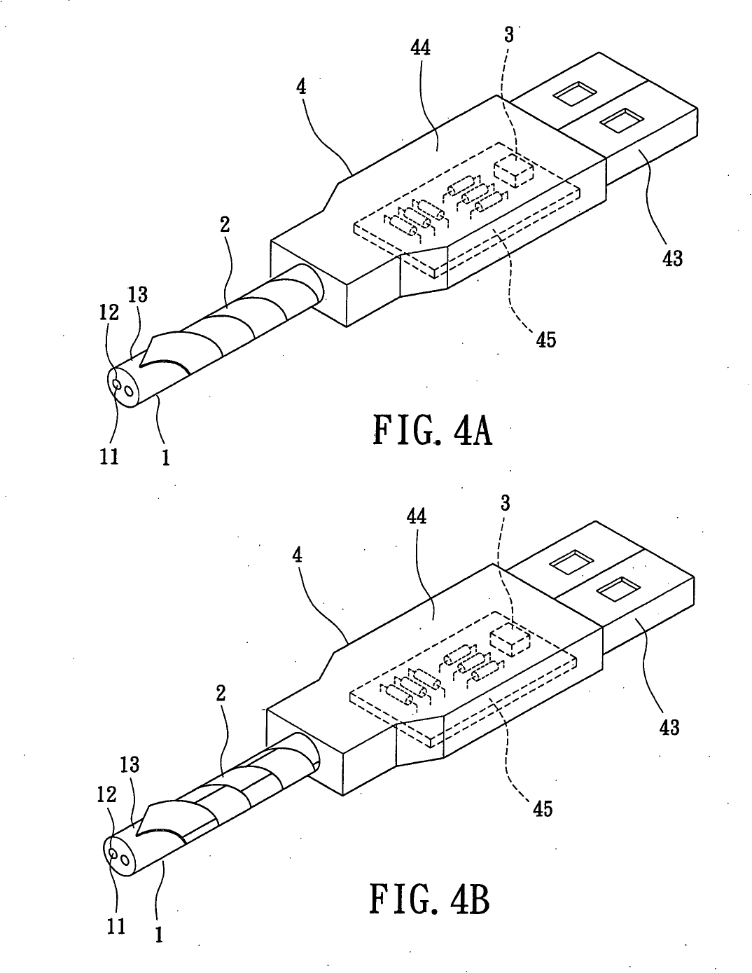

The solar-powered photoelectric layer 2 can be shaped in a long strip (as shown in FIGS. 1 and 2), or a plurality of juxtapositional pieces (as shown in FIG. 3) disposed on the flat cable. The cable 1 also can be a round cable, and the solar-powered photoelectric layer 2 can be wound around a periphery of the cable 1 in a spiral manner (as shown in FIGS. 4A and 4B). For the round cable, the solar-powered photoelectric layer 2 can also be shaped in a long strip (as shown in FIG. 4A), or a plurality of juxtapositional pieces (as shown in FIG. 4B).

The solar-powered photoelectric layer 2 has two conducting wires 21 which are electrically connected to electrodes of the solar-powered photoelectric layer 2, respectively. The two conducting wires 21 are a positive electrode and a negative electrode conducting wire, respectively. One end of the two conducting wires 21 is electrically connected to the printed circuit board 45. After the solar-powered photoelectric layer 2 absorbs solar energy and converts it into electric power, the conducting wires 21 are used to transmit electricity to the printed circuit board 45. The printed circuit board 45 can rectify the electrical current or regulate the voltage to a required electricity. Moreover, the conducting wires 21 can be replaced by other conductors, such as terminals, etc.

The accumulator 3 is disposed on the printed circuit board 45 and is electrically connected to the printed circuit board 45. The accumulator 3 can electrically connect with the solar-powered photoelectric layer 2 via the printed circuit board 45 to store electricity in the accumulator 3. The cable structure with a solar-powered layer of the present invention is accomplished through the above-mentioned structure.

The solar-powered photoelectric layer 2 of the present invention absorbs solar energy and converts it into electricity. The electricity can be stored in the accumulator 3. The electricity in the accumulator 3 can be transmitted to electronic products for saving electricity.

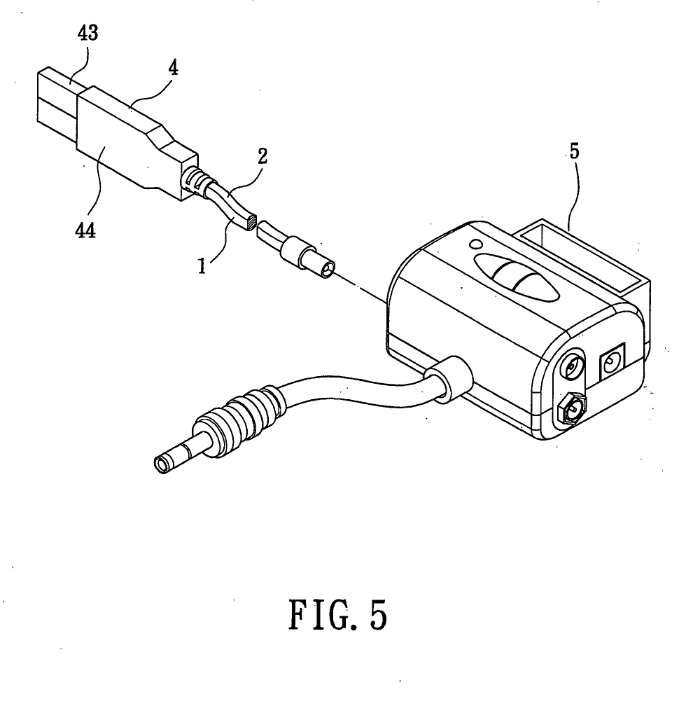

Reference is made to FIG. 5, which is a perspective view of a cable structure with a solar-powered layer of a fifth embodiment according to the present invention. The cable 1 and the conducting wire 21 of the solar-powered photoelectric layer 2 can connect with a charger 5. Electric power from the solar-powered photoelectric layer 2 can be transmitted to the charger 5 for charging electronic products or secondary cells.

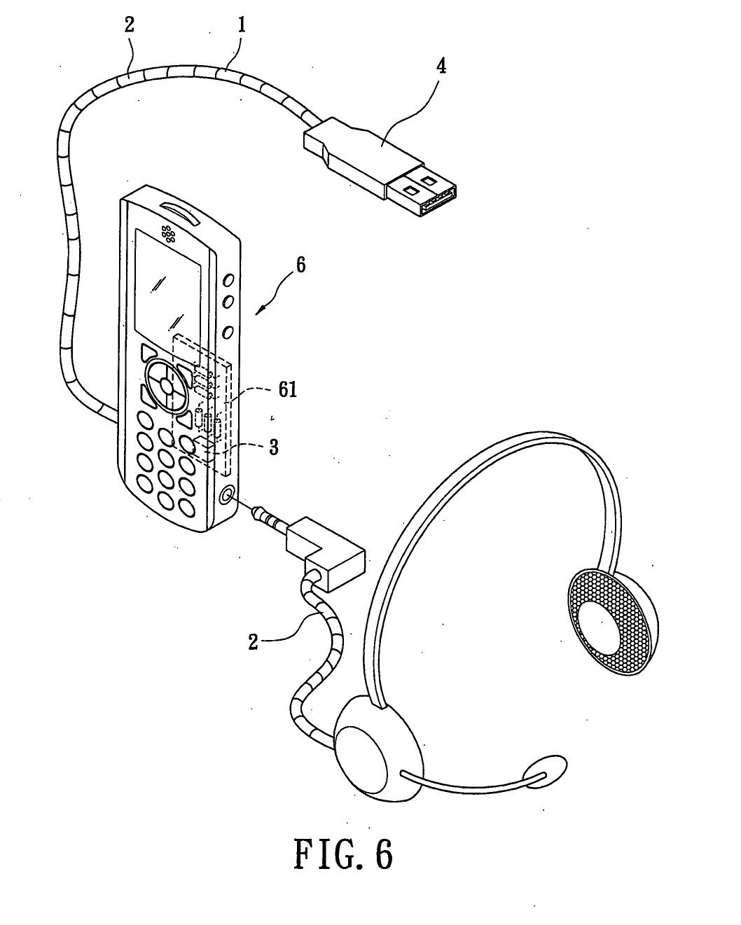

Reference is made to FIG. 6, which is a perspective view of a cable structure with a solar-powered layer of a sixth embodiment according to the present invention. The cable 1 and the conducting wire 21 of the solar-powered photoelectric layer 2 can connect with a printed circuit board 61 of an electronic product 6. The electronic product 6 can be a cell phone or an MP3 player. In this embodiment, the accumulator 3 is disposed on the printed circuit board 61 of the electronic product 6. The printed circuit board 61 can also rectify the electric current and regulate the voltage. The accumulator 3 can electrically connect with the solar-powered photoelectric layer 2 via the printed circuit board 61.

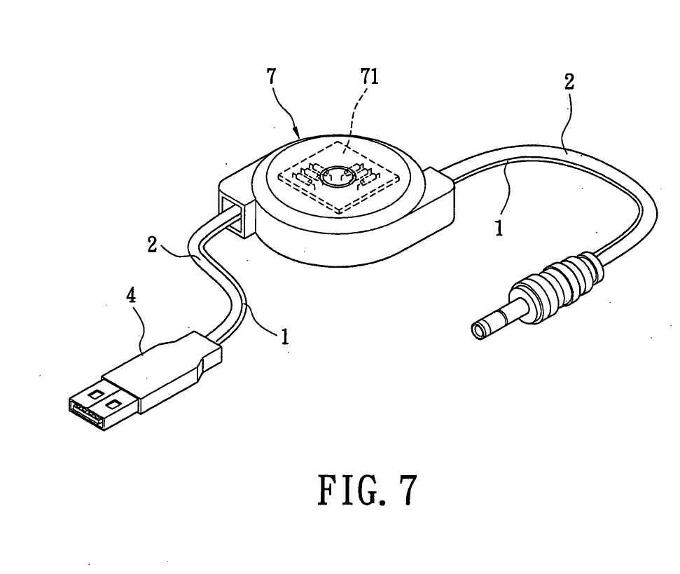

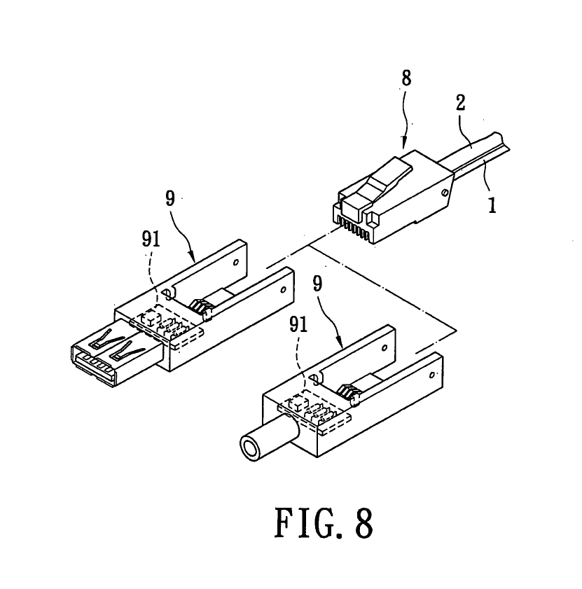

Reference is made to FIGS. 7 and 8, which are a perspective views of a cable structure with a solar-powered layer of a seventh and eighth embodiment according to the present invention. The cable 1 and the conducting wire 21 of the solar-powered photoelectric layer 2 can connect with a printed circuit board 71 of a cable winding device 7 (as shown in FIG. 7) or a plug 8 (as shown in FIG. 8). The plug 8 can connect with various types of adapters 9 (as shown in FIG. 8), for example a USB adapter or a plug adapter. The adapter 9 has a printed circuit board 91 and can electrically connect with the cable 1 and the conducting wire 21 of the solar-powered photoelectric layer 2.

The present invention has the following characteristics. The present invention mainly provides the solar-powered photoelectric layer 2 disposed on the cable 1, which enables the cable 1 to absorb solar energy and convert it into electric power. It reduces the amount of power that needs to be drawn from a power grid, and improve the inconveniences of often charging or replacing battery for electronic products.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A cable structure with a solar-powered layer, comprising:
a cable; and
at least one solar-powered photoelectric layer, disposed on a periphery of the cable.

2. The cable structure with a solar-powered layer as claimed in claim 1, wherein the cable has one end connected with an electric connector, and wherein the electric connector has a printed circuit board electrically connected with the cable.

3. The cable structure with a solar-powered layer as claimed in claim 1, wherein the cable includes a plurality of leading wires, a plurality of insulative layers covering the leading wires correspondingly and a covering layer, and the solar-powered photoelectric layer is disposed on the covering layer of the cable.

4. The cable structure with a solar-powered layer as claimed in claim 1, wherein the cable is a flat cable.

5. The cable structure with a solar-powered layer as claimed in claim 4, wherein the solar-powered photoelectric layer is disposed on a top surface and a bottom surface of the cable.

6. The cable structure with a solar-powered layer as claimed in claim 4, wherein the solar-powered photoelectric layer is disposed on a top surface or a bottom surface of the cable.

7. The cable structure with a solar-powered layer as claimed in claim 1, wherein the cable is a round cable.

8. The cable structure with a solar-powered layer as claimed in claim 7, wherein the solar-powered photoelectric layer is wound around a periphery of the cable in a spiral manner.

9. The cable structure with a solar-powered layer as claimed in claim 1, wherein the solar-powered photoelectric layer is shaped in a long strip or a plurality of juxtapositional pieces.

10. The cable structure with a solar-powered layer as claimed in claim 1, wherein the solar-powered photoelectric layer is electrically connected to a conducting element.

11. The cable structure with a solar-powered layer as claimed in claim 10, wherein the conducting element is a conducting wire or a terminal.

12. The cable structure with a solar-powered layer as claimed in claim 10, wherein the cable and the conducting element are electrically connected with a printed circuit board.

13. The cable structure with a solar-powered layer as claimed in claim 10, wherein the cable and the conducting element are electrically connected with a printed circuit board of an electronic product.

14. The cable structure with a solar-powered layer as claimed in claim 10, wherein the cable and the conducting element are electrically connected with a charger.

15. The cable structure with a solar-powered layer as claimed in claim 10, wherein the cable and the conducting element are electrically connected with an electric connector or a plug.

16. The cable structure with a solar-powered layer as claimed in claim 10, wherein the cable and the conducting element are electrically connected with a cable winding device.

17. The cable structure with a solar-powered layer as claimed in claim 1, wherein the solar-powered photoelectric layer is electrically connected to an accumulator.
